(19) United States
(12) Patent Application Publication
(10) Pub. No.: US 2012/0049387 A1
(43) Pub. Date: Mar. 1, 2012

(54) SEMICONDUCTOR DEVICE AND METHOD OF FABRICATING THE SAME

(75) Inventors: Jeong-sik YOO, Hwaseong-si (KR); Seok-chan LEE, Hwaseong-si (KR)

(73) Assignee: Samsung Electronics Co., Ltd., Suwon-si (KR)

(21) Appl. No.: 13/222,345

(22) Filed: Aug. 31, 2011

(30) Foreign Application Priority Data
Sep. 1, 2010 (KR) 10-2010-0085511

(51) Int. Cl. H01L 23/48

(52) U.S. Cl. 257/777; 257/E23.01

(57) ABSTRACT

A semiconductor device having improved physical and electrical properties includes a semiconductor chip comprising a first semiconductor substrate and a second semiconductor substrate on the first semiconductor substrate, conductive lines embedded in the first semiconductor substrate to be exposed on a surface of the first semiconductor substrate, a circuit structure formed on the second semiconductor substrate, and an external terminal formed on the circuit structure and electrically connected to the circuit structure, and an exposed surface of the first semiconductor substrate, where exposed surfaces of the conductive lines are located at the same plane.

### CROSS-REFERENCE TO RELATED APPLICATIONS

This application claims priority under 35 U.S.C. §119(a) from Korean Patent Application No. 10-2010-0085511, filed on Sep. 1, 2010, in the Korean Intellectual Property Office, the disclosure of which is incorporated herein in its entirety by reference.

### BACKGROUND OF THE INVENTION

1. Field of the Invention

The inventive concept relates to a semiconductor device and a method of fabricating the semiconductor device, and more particularly, to a semiconductor device having improved physical and electrical properties and a method of fabricating the semiconductor device.

2. Description of the Related Art

Recently, demands for highly integrated and high performance semiconductor devices with small sizes have increased continuously. Accordingly, chip sizes are being reduced and the number of electric connection terminals are being increased, and thus, limitations caused by physical properties such as a size of the semiconductor device and electrical properties such as impedance of transferring lines have become severe.

### SUMMARY OF THE INVENTION

The inventive concept provides a semiconductor device having improved physical and electrical properties and a method of fabricating the semiconductor device.

Additional features and utilities of the present general inventive concept will be set forth in part in the description which follows and, in part, will be obvious from the description, or may be learned by practice of the general inventive concept.

According to a feature of the present general inventive concept, there is provided a semiconductor device including a semiconductor chip comprising a first semiconductor substrate and a second semiconductor substrate on the first semiconductor substrate, conductive lines embedded in the first semiconductor substrate to be exposed on a surface of the first semiconductor substrate, a circuit structure formed on the second semiconductor substrate, and an external terminal formed on the circuit structure and electrically connected to the circuit structure, wherein an exposed surface of the first semiconductor substrate and exposed surfaces of the conductive lines are located at the same plane.

The semiconductor device may further include an insulating layer disposed between the first semiconductor substrate and the conductive lines. An exposed surface of the insulating layer may be located at the same plane as the exposed surface of the first semiconductor substrate.

The insulating layer may directly contact the second semiconductor substrate. The conductive lines may directly contact the second semiconductor substrate.

A surface of the semiconductor chip may expose the conductive lines, the insulating layer, and the first semiconductor substrate.

The conductive lines may be extended toward side surfaces of the semiconductor chip, and may be exposed at the side surfaces of the semiconductor chip.

The semiconductor chip may further include an adhesive layer disposed between the first semiconductor substrate and the second semiconductor substrate.

According to another feature of the present general inventive concept, a semiconductor device includes a first semiconductor chip comprising a first surface and a second surface that is opposite to the first surface, conductive lines embedded in the first surface, a circuit structure formed in the first semiconductor chip, and a first external terminal formed on the second surface and electrically connected to the circuit structure, wherein a semiconductor substrate and the conductive lines are exposed on the first surface, and the exposed surfaces of the semiconductor substrate and the conductive lines are located at the same plane.

The semiconductor device may further include an insulating layer disposed between the first semiconductor substrate and the conductive lines. An exposed surface of the insulating layer may be located at the same plane as the exposed surface of the first semiconductor substrate.

The first surface of the semiconductor chip may expose the conductive lines, the insulating layer, and the first semiconductor substrate.

The semiconductor device may further include a second semiconductor chip stacked on the first surface of the first semiconductor chip, and first bonding wires connected between the second semiconductor chip and the conductive lines.

One of the end portions of the first bonding wires may directly contact the exposed surfaces of the conductive lines.

The semiconductor device may further include a printed circuit board, on which the first semiconductor chip is mounted as a flip-chip, and the circuit structure of the first semiconductor chip may be electrically connected to the printed circuit board via the first external terminal.

The semiconductor device may further include second bonding wires connected between the first semiconductor chip and the printed circuit board, and the second semiconductor chip may be electrically connected to the printed circuit board through the first bonding wires, the conductive lines, and the second bonding wires.

The first semiconductor chip may further include a second external terminal formed on the second surface and electrically connected to the conductive lines, and the second semiconductor chip may be electrically connected to the printed circuit board through the first bonding wires, the conductive lines, and the second external terminal.

The first semiconductor chip may further include a contact plug that electrically connects the conductive lines to the second external terminal.

According to another feature of the present general inventive concept, a semiconductor device includes a semiconductor chip comprising a semiconductor substrate, and conductive lines embedded in the semiconductor substrate, wherein an exposed surface of the semiconductor substrate and exposed surfaces of the conductive lines are located at the same plane.

The semiconductor device may further include an insulating layer disposed between the first semiconductor substrate and the conductive lines. An exposed surface of the insulating layer may be located at the same plane as the exposed surface of the first semiconductor substrate.

A surface of the semiconductor chip may expose the conductive lines, the insulating layer, and the first semiconductor substrate.

According to another feature of the present general inventive concept, there a method of fabricating a semiconductor device includes a semiconductor substrate comprising an upper surface and a lower surface that is opposite to the upper surface, forming wiring trenches on the upper surface of the semiconductor substrate, forming conductive lines burying the wiring trenches, and removing a part of the lower surface of the semiconductor substrate so as to expose the conductive lines, wherein the exposed lower surface of the semiconductor substrate and the exposed surfaces of the conductive lines are located at the same plane as each other.

In yet another feature of the present general inventive concept, a semiconductor device includes a first semiconductor substrate having a first surface and including at least one conductive line formed in the first semiconductor substrate such that an exposed surface of the at least one conductive line is flush with the first surface of the semiconductor substrate, and a circuit structure disposed against the first semiconductor substrate and in electrical communication with the at least one conductive line.

### BRIEF DESCRIPTION OF THE DRAWINGS

These and/or other features and utilities of the present general inventive concept will become apparent and more readily appreciated from the following description of the exemplary embodiments, taken in conjunction with the accompanying drawings of which:

FIG. 1 is a schematic perspective view of a first semiconductor chip included in a semiconductor device according to an exemplary embodiment of the present general inventive concept;

FIG. 2 is a cross-sectional view of the first semiconductor chip of FIG. 1 taken along line A-A;

FIG. 3 is a schematic perspective view of a semiconductor device according to another exemplary embodiment of the present general inventive concept;

FIGS. 4 through 10 are diagrams illustrating processes of fabricating a semiconductor device according to an exemplary embodiment of the present general inventive concept;

FIG. 11 is a schematic perspective view of a first semiconductor chip included in a semiconductor device according to an exemplary embodiment of the present general inventive concept;

FIG. 12 is a cross-sectional view of the first semiconductor chip of FIG. 11 taken along line B-B;

FIG. 13 is a schematic perspective view of a semiconductor device according to another exemplary embodiment of the present general inventive concept;

FIGS. 14 through 19 are diagrams illustrating processes of fabricating a semiconductor device according to another exemplary embodiment of the present general inventive concept;

FIGS. 20 through 22 are schematic perspective views of semiconductor devices according to exemplary embodiments of the present general inventive concept; and

FIG. 23 is a cross-sectional view of the semiconductor device of FIG. 22 taken along line C-C.

### DETAILED DESCRIPTION OF THE PREFERRED EMBODIMENTS

Reference will now be made in detail to exemplary embodiments of the present general inventive concept, examples of which are illustrated in the accompanying drawings, wherein like reference numerals refer to the like elements throughout. The exemplary embodiments are described below in order to explain the present general inventive concept while referring to the figures.

This present general inventive concept may, however, be embodied in many different forms and should not be construed as limited to the exemplary embodiments set forth herein; rather, these exemplary embodiments are provided so that this disclosure will be thorough and complete, and will fully convey the scope of the present general inventive concept to those skilled in the art. Although a few exemplary embodiments of the present general inventive concept have been shown and described, it would be appreciated by those skilled in the art that changes may be made in these exemplary embodiments without departing from the principles and spirit of the present general inventive concept, the scope of which is defined in the claims and their equivalents.

The terminology used herein is for the purpose of describing particular exemplary embodiments only and is not intended to be limiting of the present general inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that although the terms first and second are used herein to describe various elements, these elements should not be limited by these terms. These terms are only used to distinguish one element from another element. Thus, a first element discussed below could be termed a second element, and similarly, a second element may be termed a first element without departing from the teachings of this disclosure.

Unless otherwise defined, all terms (including technical and scientific terms) used herein have the same meaning as commonly understood by one of ordinary skill in the art to which this present general inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

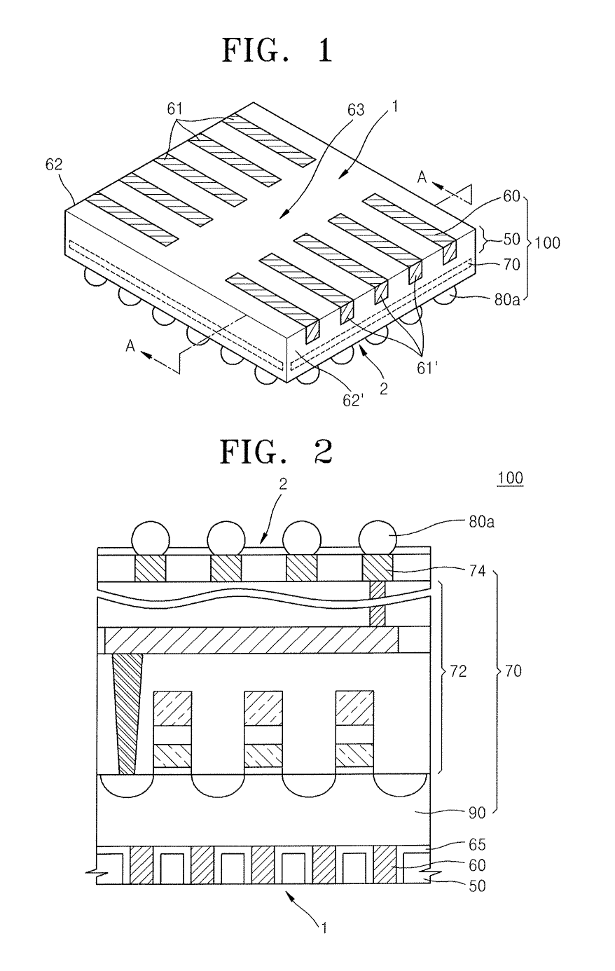

FIG. 1 is a schematic perspective view of a first semiconductor chip 100 included in a semiconductor device according to an exemplary embodiment of the present general inventive concept. FIG. 2 is a cross-sectional view of the first semiconductor chip 100 of FIG. 1 taken along line A-A.

Referring to FIG. 1, the first semiconductor chip 100 in the semiconductor device may include a first semiconductor substrate 50, a circuit structure 70, and conductive lines 60.

The first semiconductor substrate 50 may include a semiconductor material, for example, a group-IV semiconductor, a group III-V compound semiconductor, or a group II-VI oxide semiconductor. For example, the group-IV semiconductor may include silicon, germanium, or silicon-germanium. The first semiconductor substrate 50 may include a bulk wafer, an epitaxial layer, a silicon-on-insulator (SOI) layer, and/or a semiconductor-on-insulator (SEOI) layer.

The conductive lines 60 may be embedded in the first semiconductor substrate 50. Each of the conductive lines 60 are separated and electrically insulated from one another via a portion of the first surface 1. The embedded conductive lines 60 may extend symmetrically from a center of the first semiconductor substrate 50 toward side surfaces of the first semiconductor chip 100. In at least one exemplary embodiment illustrated in FIG. 1, a first group 61 of conductive lines 60 are aligned along a first side 62 of the first semiconductor chip 50, and a second group 61′ of conductive lines 60 are aligned along a second side 62′ of the first semiconductor ship 50. The first group 61 and the second group 61′ are spaced apart from each other by a center area 63 of the first surface 1. Each conductive line 60 included in the first group 61 extends from the center area 63 to the first side 62, and each conductive line 60 included in the second group 61′ extends from the center area 63 to the second side 62′. Moreover, the conductive lines 60 may be exposed at the side surfaces of the first semiconductor chip 100. The conductive lines 60 may include one selected from the group including of impurity-doped silicon, polysilicon, metal such as aluminum (Al), copper (Cu), and tungsten (W), nitride material of the metal such as titanium (Ti) and W, silicide of fire-resistant metal such as Ti, W, and cobalt (Co), and combinations thereof.

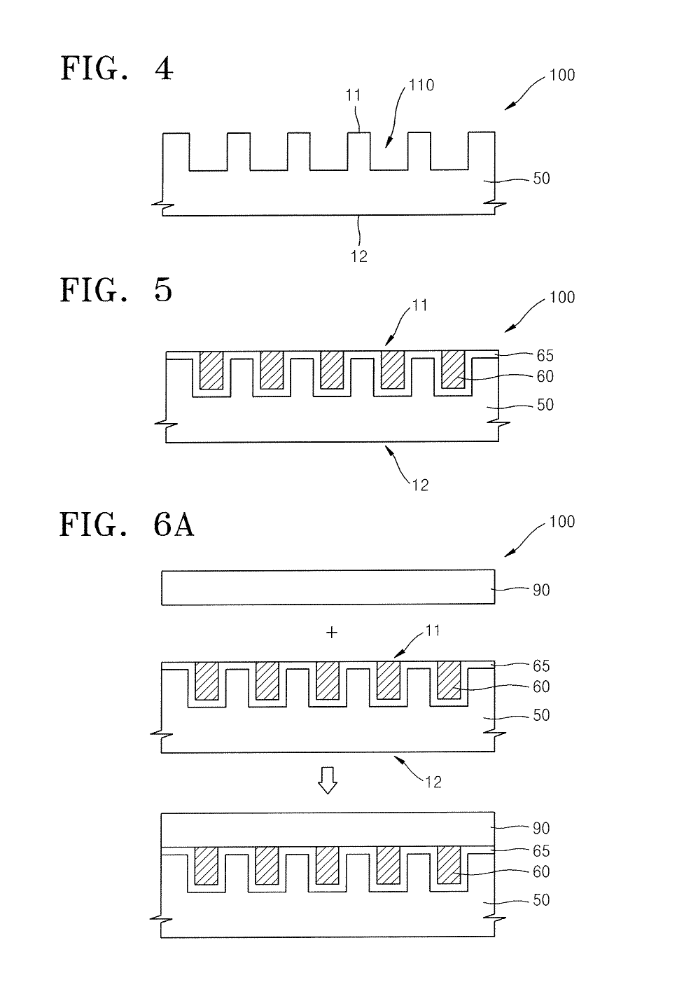

An exposed surface of the first semiconductor substrate 50 and exposed surfaces of the conductive lines 60 may be located at the same plane as each other. In more detail, a first surface 1 of the first semiconductor chip 100 may be planarized by a chemical mechanical polishing (CMP) process. Then, the surfaces of the first semiconductor substrate 50 and the conductive lines 60 may be exposed. During the planarization process, an insulating layer 65 may function as an etch stop layer. In addition, the exposed surfaces of the first semiconductor substrate 50 and the conductive lines 60 may substantially have the same heights as each other. This will be described in more detail with reference to FIGS. 4 through 10. Accordingly, since the conductive lines 60 are embedded in the first semiconductor substrate 50 and are flush with the first surface 1, a second semiconductor chip may be disposed on top of the conductive lines 60 and the first surface 1 such that the overall size of the semiconductor device may be decreased, as discussed in greater detail below.

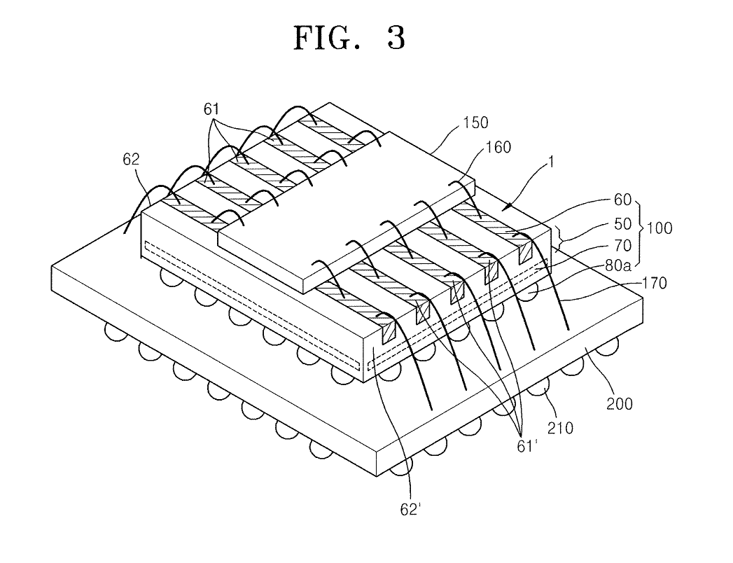

Alternatively, the first semiconductor chip 100 may further include a first external terminal 80a. The first external terminal 80a may be formed on a second surface 2 that is opposite to the first surface 1, and may be electrically connected to the circuit structure 70. In more detail, the first semiconductor chip 100 may be flip-chip bonded to a printed circuit board (PCB) 200 (refer to FIG. 3), and in this case, the first external terminal 80a may be a solder bump.

Referring to FIG. 2, the first semiconductor chip 100 may further include the insulating layer 65 that is disposed between the first semiconductor substrate 50 and the conductive lines 60. As described above, the first surface 1 of the first semiconductor chip 100 may be planarized in the above method, and thus, the exposed surface of the insulating layer 65 may be located at the same level as that of the first semiconductor substrate 50. In addition, as a result of the planarization process of the first semiconductor substrate 50, the first semiconductor substrate 50, the conductive lines 60, and the insulating layer 65 may be exposed on the first surface 1 of the first semiconductor chip 100.

The circuit structure 70 may be formed in the first semiconductor chip 100. The circuit structure 70 may be realized on a second semiconductor substrate 90. In FIG. 2, a flash memory cell structure 72 of a floating gate type is shown as the circuit structure 70; however, the present general inventive concept is not limited thereto. That is, the circuit structure 70 may be realized in various types, for example, a non-volatile memory device, a volatile memory device, and a digital signal processor (DSP). To electrically connect to the outside, the circuit structure 70 may be electrically connected to the first external terminal 80a through a chip pad 74.

FIG. 3 is a schematic perspective view of a semiconductor device according to another exemplary embodiment of the present general inventive concept. The semiconductor device of the at least one exemplary embodiment may include the first semiconductor chip 100 shown in FIGS. 1 and 2. Hereinafter, descriptions of the same elements in the previous and other exemplary embodiments will not be provided.

Referring to FIG. 3, the semiconductor device may include the PCB 200, the first semiconductor chip 100, a second semiconductor chip 150, first bonding wires 160, and second bonding wires 170.

The PCB 200 may include a structure in which an insulating layer, such as epoxy resin, polyimide resin, bismaleimide triazine (BT) resin, frame retardant 4 (RF-4), FR-5, ceramic, silicon, or glass, and wiring patterns are stacked. The PCB 200 may include the first semiconductor chip 100, and in particular, may be a flip-chip type PCB. In this case, the circuit structure 70 in the first semiconductor chip 100 may be electrically connected to the PCB 200 through the first external terminal 80a. The PCB 200 may be electrically connected to an external device (not shown), such as a mother board, through an external terminal 210.

The second semiconductor chip 150 may be stacked on the first surface 1 of the first semiconductor chip 100. The second semiconductor chip 150 may be a different kind of chip from the first semiconductor chip 100. Therefore, the second semiconductor chip 150 may have different size and pad arrangement from those of the first semiconductor chip 100. The second semiconductor chip 150 may be stacked on the first surface 1 of the first semiconductor chip 100 with an adhesive tape such as a die attach film (DAF).

The first bonding wires 160 may be connected between the second semiconductor chip 150 and the conductive lines 60. In addition, the second bonding wires 170 may be connected between the conductive lines 60 and the PCB 200. In this case, one of the end portions of the first bonding wires 160 and one of the end portions of the second bonding wires 170 may be wire-bonded so as to directly contact the exposed portions of the conductive lines 60. Therefore, the second semiconductor chip 150 may be electrically connected to the PCB 200 via the first bonding wires 160, the conductive lines 60, and the second bonding wires 170.

When the second semiconductor chip 150 is stacked on the first semiconductor chip 100 in the flip-chip type semiconductor device, the second semiconductor chip 150 and the PCB 200 are electrically connected to each other by bonding wires that directly connect the second semiconductor chip 150 to the PCB 200. However, in this case, the bonding wires extending from the second semiconductor chip 150 to the PCB 200 have long lengths, that is, high resistances, and thus, a problem of signal integrity occurs.

However, in the semiconductor device according to at least one exemplary embodiment of the present general inventive concept, the second semiconductor chip 150 and the PCB 200 may be electrically connected to each other by the conductive lines 60, such that the impedance may be decreased, e.g., to nearly 0. In addition, the first bonding wires 160, and the second bonding wires 170 may be formed using relatively short lengths as compared to the conventional method, and thus, the signal integrity problem of the semiconductor device may be improved.

FIGS. 4 through 10 are diagrams illustrating a method of fabricating the semiconductor device of FIG. 3, according to at least one exemplary embodiment of the present general inventive concept. Hereinafter, descriptions of the same elements in the previous and other exemplary embodiments will not be provided.

Referring to FIG. 4, the first semiconductor substrate 50 of the first semiconductor chip 100 is provided, and one or more wiring trenches 110 may be formed in an upper surface 11 of the first semiconductor substrate 50. To form the wiring trench 110, mask patterns (not shown) defining locations of the wiring trenches 110 are formed, and the first semiconductor substrate 50 may be etched by using the mask patterns as an etching mask.

Referring to FIG. 5, the conductive lines 60 are formed and, are disposed in the wiring trenches 110. Before forming the conductive lines 60, the insulating layer 65 may be formed on the wiring trenches 110. In this case, the insulating layer 65 may be disposed between the conductive lines 60 and the fist semiconductor substrate 50.

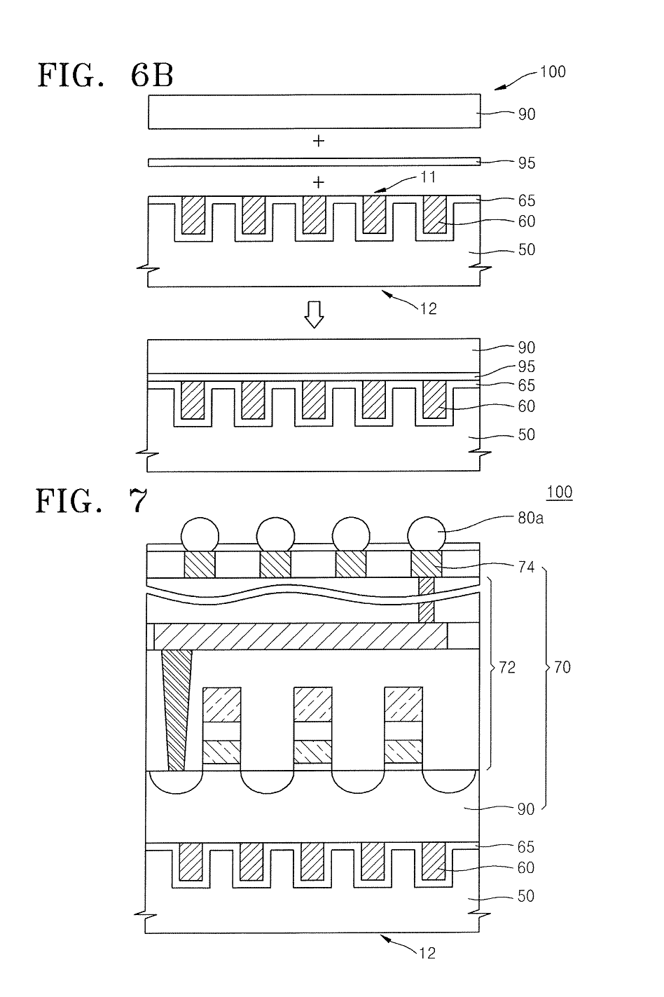

Referring to FIGS. 6A and 6B, the first and second semiconductor substrates 50 and 90 are bonded to each other. As shown in FIG. 6A, the upper surface 11 of the first semiconductor substrate 50 may be directly bonded to the second semiconductor substrate 90. More specifically, the first semiconductor substrate 50 and the second semiconductor substrate 90 contact each other, and then, the first and second semiconductor substrates 50 and 90 may be annealed at a temperature of about 1,000° C. or higher under a pressure of 100 to 15,000 psi. In this case, the conductive lines 60 may directly contact the second semiconductor substrate 90. Likewise, the insulating layer 65 may directly contact the second semiconductor substrate 90.

On the other hand, as shown in FIG. 6B, the upper surface 11 of the first semiconductor substrate 50 and the second semiconductor substrate 90 may be bonded to each other with an adhesive layer 95. The adhesive layer 95 may be an organic layer having adhesive properties, for example, benzocyclobutene (BCB) produced in the name of CYCLOTENE by Dow, Corp.

Referring to FIG. 7, the circuit structure 70, including the flash memory cell structure 72 of a floating gate type and a chip pad 74 electrically connected to the flash memory cell structure 72, may be formed on the second semiconductor substrate 90. As described above, the circuit structure 70 is not limited to the flash memory cell structure 72. After that, the first external terminal 80a that is electrically connected to the chip pad 74 may be formed.

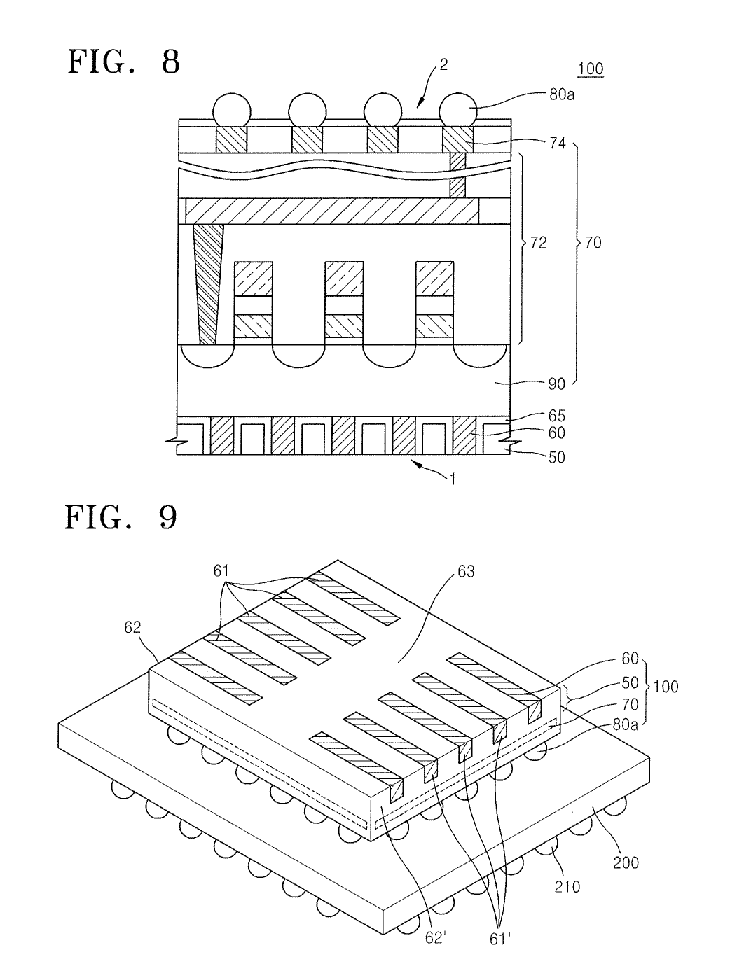

Referring to FIG. 8, a back-grinding or a back-lap process of the first semiconductor chip 100 is performed. In more detail, the back-grinding or the back-lap to remove the semiconductor material formed on a lower surface 12(see FIG. 7) of the first semiconductor substrate 50 may be performed until surfaces of the conductive lines 60 are exposed.

Through the back-grinding or the back-lap process, the second semiconductor substrate 90, the conductive lines 60, and the insulating layer 65 may be exposed on the first surface 1 of the first semiconductor chip 100. In addition, as described above, after performing the back-grinding or the back-lap process, the surfaces of the semiconductor substrate and the conductive lines 60, being exposed on the first surface 1 of the first semiconductor chip 100 or the lower surface 12 of the second semiconductor substrate 90, may be located at the same plane as each other.

In the conventional semiconductor device, the redistribution process of a semiconductor chip may be considered in order to solve the problem of spatial limitation. However, for flip-chip bonding of the semiconductor chip, the back-grinding or the back-lap process of the semiconductor chip should be performed first, and in this case, a thickness of the semiconductor chip becomes too thin to handle the semiconductor chip. Consequently, it is difficult to perform the redistribution process of the semiconductor chip.

However, according to at least one exemplary embodiment, the conductive lines 60, such as the redistribution lines, may be exposed after the back-grinding or the back-lap process of the first semiconductor chip 100. Therefore, the stacked chip structure may be electrically connected to the PCB via the conductive lines 60 in a narrow space without performing additional redistribution process. Thus, the spatial limitation problem of the semiconductor device may be solved.

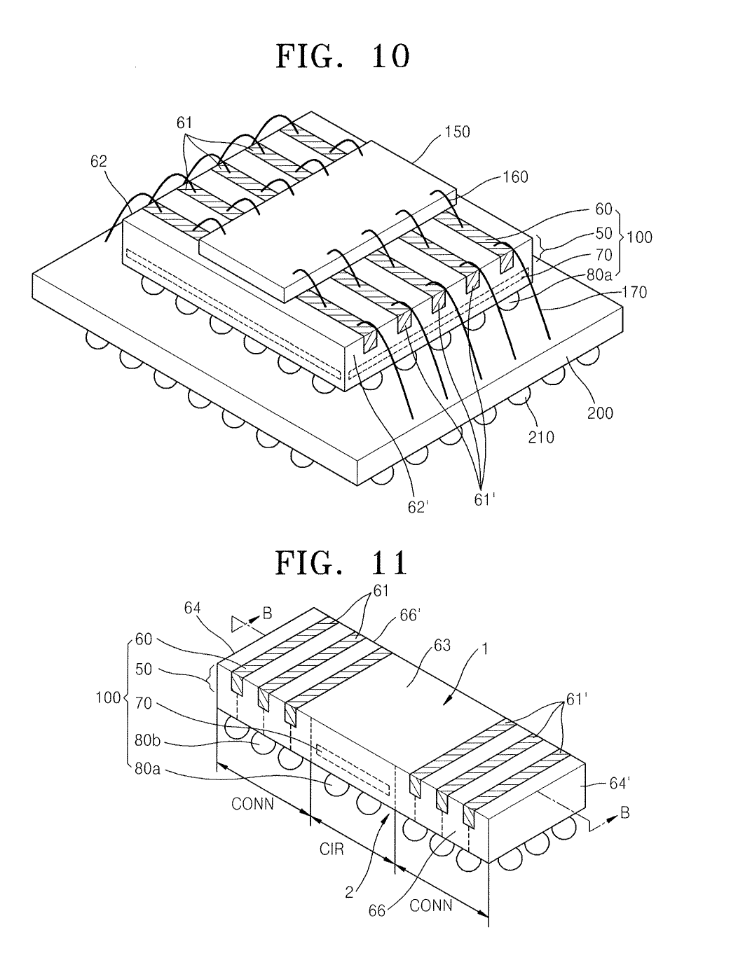

Referring to FIG. 9, the first semiconductor chip 100 is mounted on the PCB 200. In this case, the circuit structure 70 may be electrically connected to the PCB 200 through the first external terminal 80a. Although not shown in FIG. 9, the first semiconductor chip 100 may be formed by a dicing or singulation process of a wafer (not shown) on which the first semiconductor substrate 50 including the conductive lines 60, the second semiconductor substrate 90, the circuit structure 70, and the chip pad 74 are formed.

Referring to FIG. 10, the second semiconductor chip 150 is stacked on the first surface 1 of the first semiconductor chip 100. After that, the wire bonding process of the second semiconductor chip 150 and the conductive lines 60 is performed using the first bonding wires 160, and the wire bonding process of the conductive lines 60 and the PCB 200 is performed using the second bonding wires 170.

The order of performing the processes illustrated in FIGS. 9 and 10 is not limited to the shown order. For example, the second semiconductor chip 150 may be stacked on the first semiconductor chip 100, and then, the wire bonding process to electrically connect the second semiconductor chip 150 to the conductive lines 60 may be performed using the first bonding wires 160. After that, the first semiconductor chip 100 may be mounted on the PCB 200, and then, the wire bonding process to electrically connect the conductive lines 60 to the PCB 200 may be performed using the second bonding wires 170.

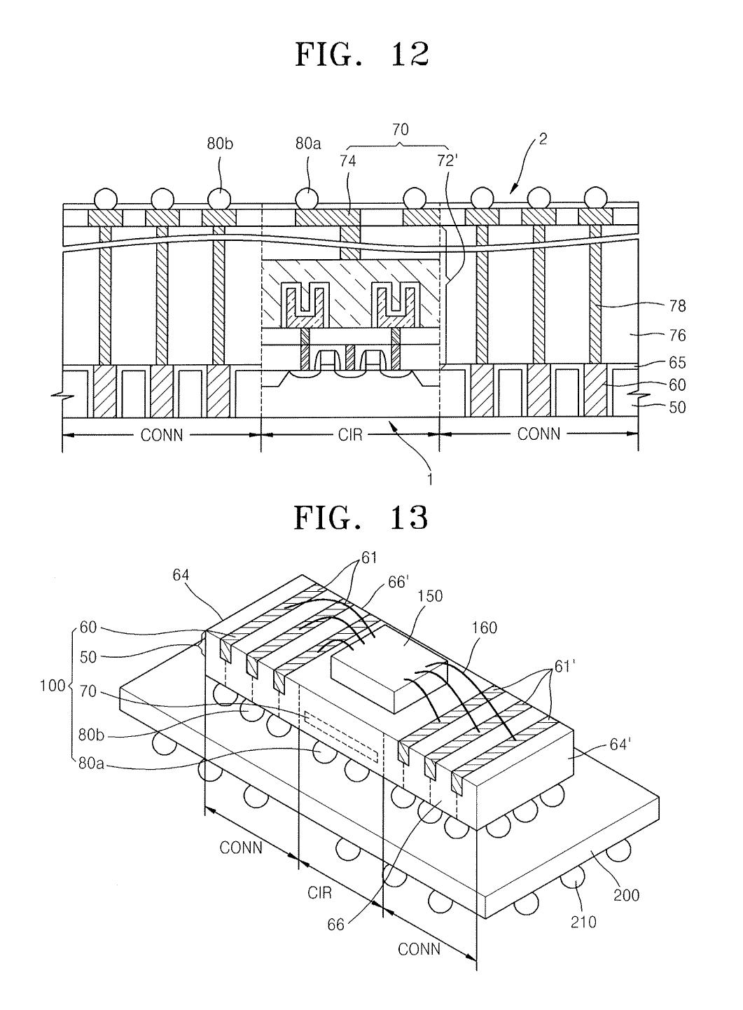

FIG. 11 is a schematic perspective view of the first semiconductor chip 100 included in a semiconductor device according to another exemplary embodiment of the present general inventive concept.

In the exemplary embodiment of FIG. 11, a first group 61 of conductive lines 60 are aligned along a first end 64 of the first semiconductor chip 50, and a second group 61′ of conductive lines 60 are aligned along a second end 64 of the first semiconductor ship 50. Each of the conductive lines 60 are separated and electrically insulated from one another via a portion of the first surface 1. The first group 61 and the second group 61′ are spaced apart from each other by a center area 63 of the first surface 1. Each conductive line 60 included in the first group 61 extends parallel to the first end 64, and extends between a first side 66 and a second side 66′ of the semiconductor chip 50. Similarly, each conductive line 60′ included in the second group 61′ extends parallel to the second end 64′, and between the first side 66 and the second side 66′ of the semiconductor chip 50.

FIG. 12 is a cross-sectional view of the semiconductor chip 100 taken along line B-B of FIG. 11. FIG. 13 is a schematic perspective view of the semiconductor device according to the at least one exemplary embodiment of the present general inventive concept. The semiconductor device of at least one exemplary embodiment may be a modification of the first semiconductor chip 100 and the semiconductor device illustrated in FIGS. 1 through 3. Hereinafter, descriptions of the same elements in the previous and the other exemplary embodiments will not be provided.

Referring to FIGS. 11 and 12, the first semiconductor chip 100 may include the first semiconductor substrate 50, the circuit structure 70, the first external terminal 80a, and a second external terminal 80b. Referring to FIG. 13, the semiconductor device may include the PCB 200, the first semiconductor chip 100, the second semiconductor chip 150, and the first bonding wires 160. As described above, the first semiconductor substrate 50 may include the conductive lines 60 and the insulating layer 65. In addition, as described above, in FIG. 12, a dynamic random access memory (DRAM) memory cell structure is shown as the circuit structure 70; however, the present general inventive concept is not limited thereto.

In the first semiconductor chip 100 and the semiconductor device illustrated in FIGS. 1 through 3, the first semiconductor substrate 50 including the conductive lines 60, and the second semiconductor substrate 90 are bonded to each other, and the circuit structure 70 may be formed on the second semiconductor substrate 90. However, in the first semiconductor chip 100 and the semiconductor device illustrated in FIGS. 11 through 13, the circuit structure 70 is directly formed on the first semiconductor substrate 50 including the conductive lines 60. Therefore, an additional bonding process of semiconductor substrates is not necessary.

In addition, in the first semiconductor chip 100 and the semiconductor device illustrated in FIGS. 1 through 3, the second semiconductor chip 150 is electrically connected to the PCB 200 via the first bonding wires 160, the conductive lines 60, and the second bonding wires 170. However, in the first semiconductor chip 100 and the semiconductor device illustrated in FIGS. 11 through 13, a contact plug 78 formed in the first semiconductor chip 100 may be used instead of the second bonding wires 170. In this case, the second semiconductor chip 150 may be electrically connected to the PCB 200 via the first bonding wires 160, the conductive lines 60, the contact plug 78, and the second external terminal 80b.

FIGS. 14 through 19 are diagrams illustrating a method of fabricating the semiconductor device of FIG. 11, according to another exemplary embodiment of the present general inventive concept. The method of fabricating the semiconductor device of at least one embodiment may be a partial a modification of the method described with reference to FIGS. 4 through 10. Hereinafter, descriptions of the same elements in the previous and other exemplary embodiments will not be provided.

Referring to FIG. 14, the first semiconductor substrate 50 is provided, and the wiring trenches 110 are formed in the upper surface 11 of the first semiconductor substrate 50. In more detail, the wiring trenches 110 are formed in a connecting region CONN of the first semiconductor substrate 50. To form the circuit structure 70, which is discussed further below, the wiring trenches 110 may not be formed in a circuit region CIR of the first semiconductor substrate 50.

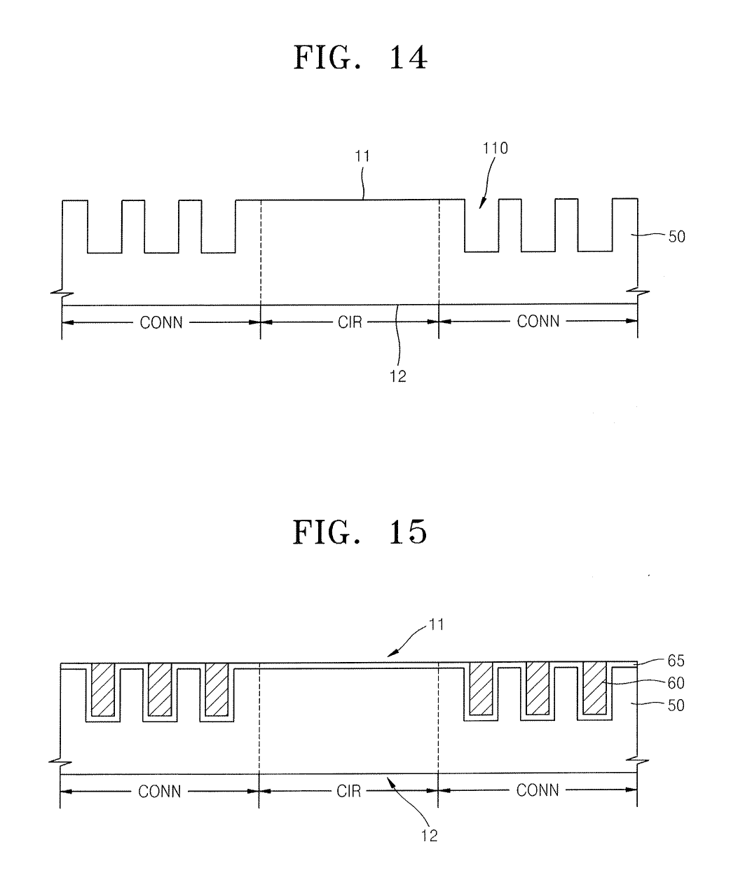

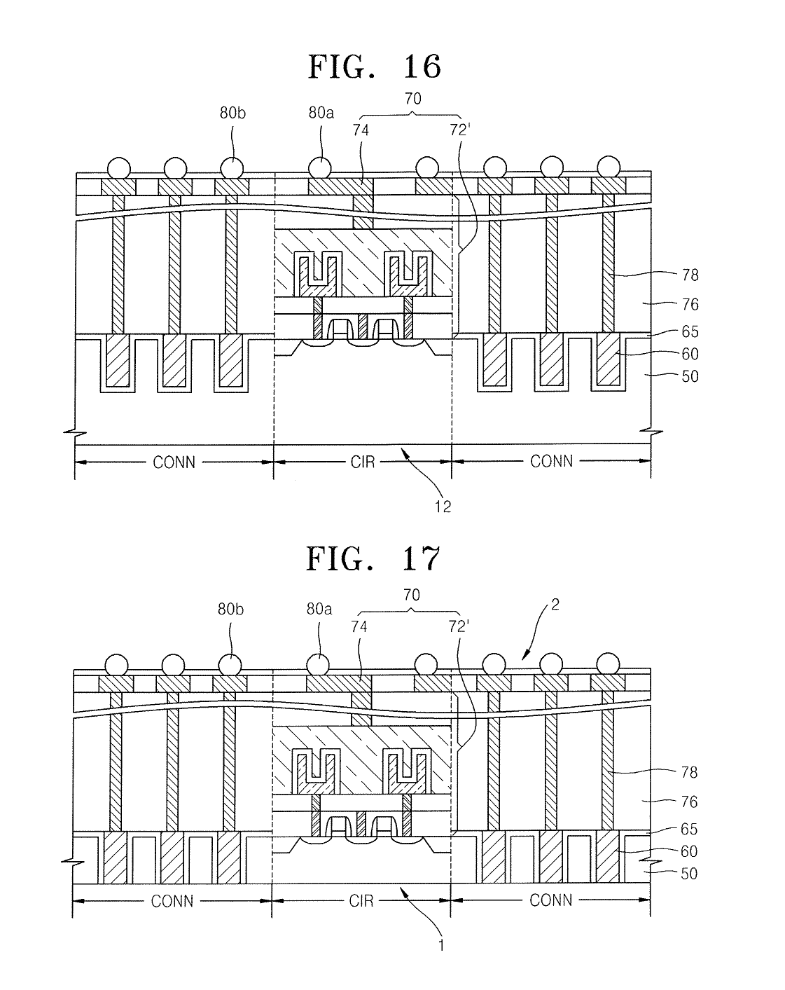

Referring to FIG. 15, the conductive lines 60 are formed to bury the wiring trenches 110 and the insulating layer 65. When the wiring trenches 110 are only formed in the connecting region CONN of the first semiconductor substrate 50, the conductive lines 60, burying the wiring trenches 110, may be also formed only in the connecting region CONN of the first semiconductor substrate 50.

Referring to FIG. 16, the circuit structure 70, including a DRAM memory cell structure 72′, and the chip pad 74 that is electrically connected to the DRAM memory cell structure 72′ may be formed in the circuit region CIR of the first semiconductor substrate 50. An interlayer dielectric 76 and the contact plug 78 that penetrates through the interlayer dielectric 76 to contact the conductive lines 60 are formed in the connecting region CONN of the first semiconductor substrate 50. After that, the first external terminal 80a that is electrically connected to the chip pad 74 may be formed, and the second external terminal 80b that is electrically connected to the contact plug 78 via the chip pad 74 is formed.

Referring to FIG. 17, the back-grinding or the back-lap process of the first semiconductor chip 100 may be performed. As described above, the back-grinding or the back-lap process to remove the semiconductor material formed on the lower surface 12 of the first semiconductor substrate 50 may be performed until surfaces of the conductive lines 60 are exposed.

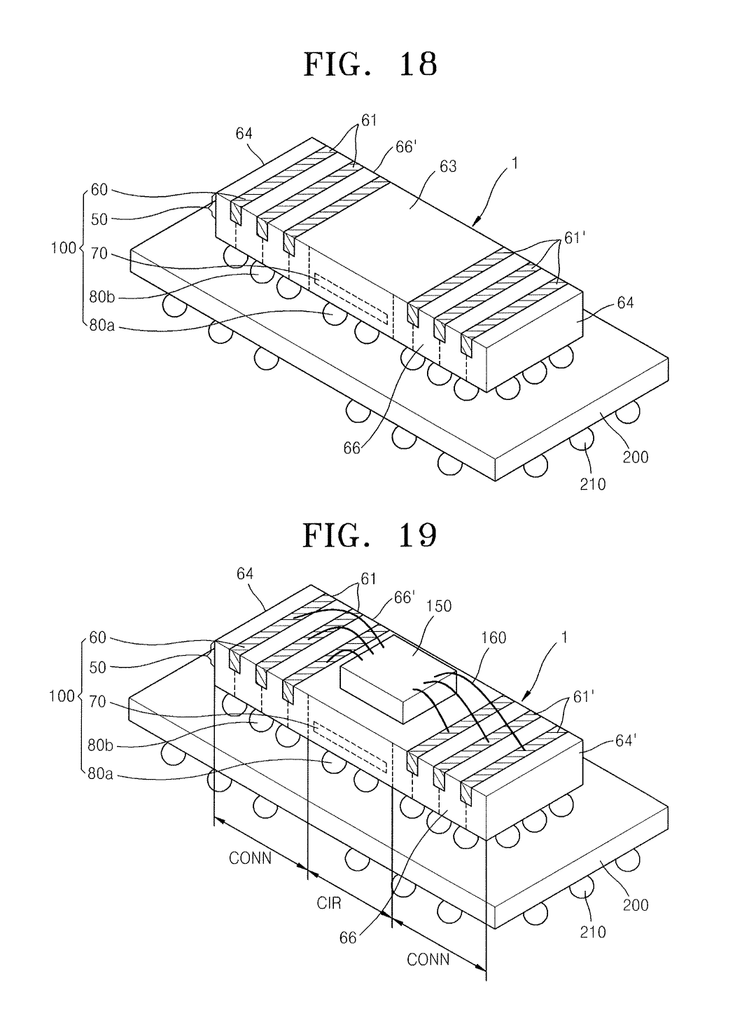

Referring to FIGS. 18 and 19, the first semiconductor chip 100 is mounted on the PCB 200, and the second semiconductor chip 150 is stacked on the first surface 1 of the first semiconductor chip 100. In this case, the circuit structure 70 may be electrically connected to the PCB 200 through the first external terminal 80a. On the other hand, the second semiconductor chip 150 may be electrically connected to the PCB 200 through the first bonding wires 160, the conductive lines 60, and the second external terminal 80b.

As described with reference to FIGS. 9 and 10, the order of performing the processes illustrated in FIGS. 18 and 19 is not limited to the order shown in the drawings. As an example, a wafer level-chip stack package (WL-CSP) process may be performed, that is, the second semiconductor chip 150 may be stacked on a wafer (not shown), on which the first semiconductor substrate 50 including the conductive lines 60, the circuit structure 70 formed on the second semiconductor substrate 90, and the chip pad 74 are formed. After that, the singulation process of the wafer may be performed and the WL-CSP may be mounted on the PCB 200.

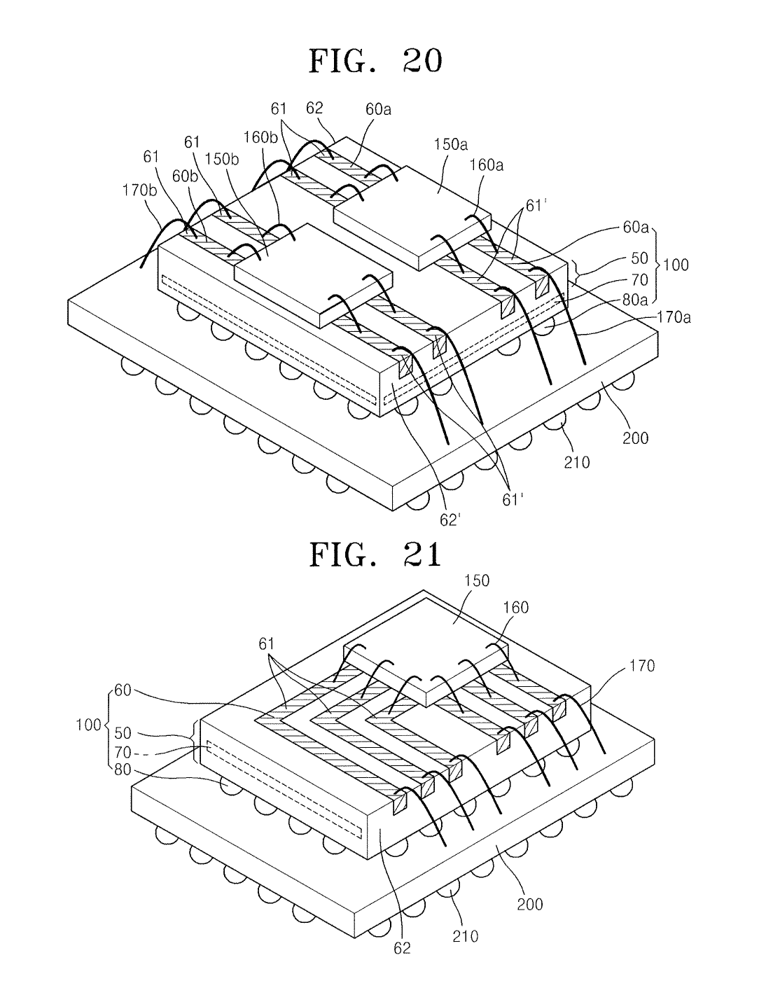

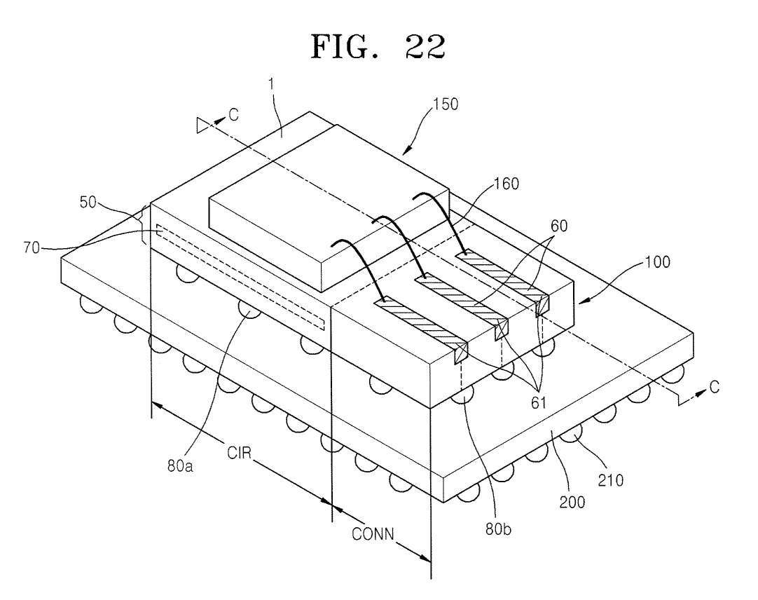

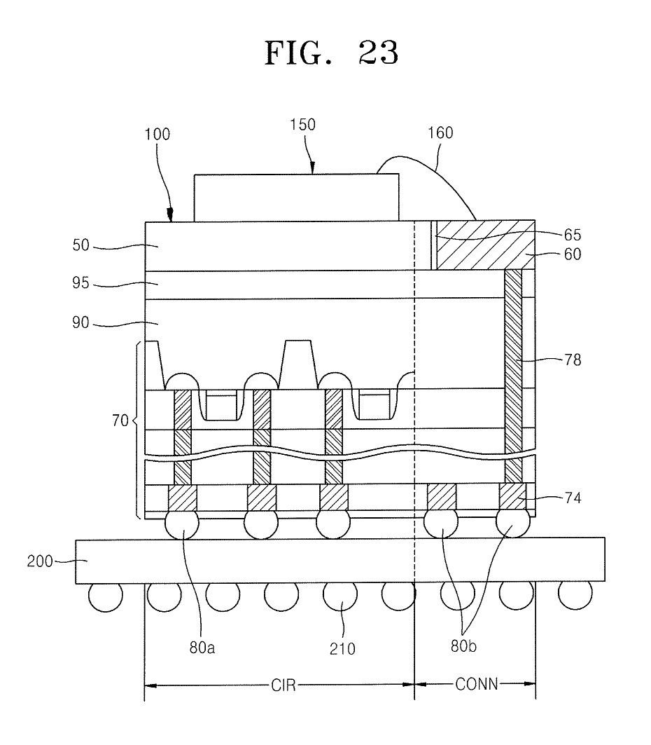

FIGS. 20 through 22 are schematic perspective views illustrating a semiconductor device according to another exemplary embodiment of the present general inventive concept. FIG. 23 is a cross-sectional view of the semiconductor device taken along line C-C of FIG. 22. The semiconductor device of at least one exemplary embodiment may be a partial modification of the semiconductor device illustrated in FIG. 3. Thus, descriptions of the same elements in the semiconductor device of FIG. 3 and other exemplary embodiments will not be provided.

Referring to FIG. 20, another exemplary embodiment of a semiconductor device according to the present general inventive concept includes a plurality of second semiconductor chips 150a and 150b stacked on the first semiconductor chip 100. Similar to the semiconductor device illustrated in FIGS. 1-3, each of the first and second semiconductor chips 150a and 150b are coupled to first and second groups of conductive lines 60. The respective first and second groups of conductive lines are aligned along first and second sides 62 and 62′ of the first semiconductor chip 50. The respective first and second groups 61 and the second group 61′ are spaced apart from each other by a center area 63 of the first surface 1. Each conductive line 60 included in the respective first and second groups 61 and 61′ extends from the center area 63 to the first side 62, and each conductive line 60 included in the second group 61′ extends from the center area 63 to the second side 62′. Each of the second semiconductor chips 150a and 150b in the semiconductor device illustrated in FIG. 20 may be electrically connected to the PCB 200 through first bonding wires 160a or 160b, conductive lines 60a or 60b, and second bonding wires 170a or 170b. For example, the first bonding wires 160b may electrically connect the semiconductor chips 150a and 150b to respective first groups of conducting lines, while the second bonding wires 160a may electrically connect the semiconductor chips 150a and 150b to respective second groups of conducting lines. The second bonding wires 170b may electrically connect each of the respective first groups of conducting lines to the PCB 200, while the second bonding wires 170a may electrically connect each of the respective second groups of conducting lines to the PCB 200.

Referring to FIG. 21, the conductive lines 60 are not limited straightly extended structures, and may extend as bent and/or curved structures. That is, the conductive lines 60 may perform as redistribution lines. For example, the conductive lines 60 illustrated in the exemplary embodiment of FIG. 21 have a bent shape. However, the shape of the conductive lines 60 is not limited thereto.

Referring to FIGS. 22 and 23, in the first semiconductor chip 100 in which the first semiconductor substrate 50 and the second semiconductor substrate 90 are bonded to each other by the adhesive layer 95 (see FIG. 23), the circuit region CIR and the connecting region CONN may be separately formed. The second semiconductor chip 150 may be disposed on a surface of the first semiconductor chip and in the circuit region CIR. The conductive lines 60 may be formed in the connecting region CONN of the first semiconductor chip 100. First bonding wires 160 may connect the second semiconductor chip 150 to respective conductive lines 60.

Referring to FIG. 23, in this case, the contact plug 78 may be formed in the connecting region CONN, and may penetrate through the adhesive layer 95. The contact plug 78 may include a first end in electrical contact with a conductive line 60, and a second end in electrical contact with a chip pad 74 to electrically connect the conductive lines 60 to the second external terminal 80b.

The circuit structure 70 of the first semiconductor chip 100 may be electrically connected to the PCB 200 through the first external terminal 80a. The second semiconductor chip 150 stacked on the first semiconductor chip 100 may be electrically connected to the PCB 200 through the first bonding wires 160, the conductive lines 60 of the first semiconductor chip 100, the contact plug 78, and the second external terminal 80b.

Although a few exemplary embodiments of the present general inventive concept have been shown and described, it will be appreciated by those skilled in the art that changes may be made in these exemplary embodiments without departing from the principles and spirit of the present general inventive concept, the scope of which is defined in the appended claims and their equivalents.

What is claimed is:

1. A semiconductor device comprising:
a semiconductor chip comprising a first semiconductor substrate and a second semiconductor substrate on the first semiconductor substrate;
conductive lines embedded in the first semiconductor substrate to be exposed on a surface of the first semiconductor substrate; and
a circuit structure formed on the second semiconductor substrate;
wherein an exposed surface of the first semiconductor substrate and exposed surfaces of the conductive lines are located at the same plane.

2. The semiconductor device of claim 1, further comprising an insulating layer disposed between the first semiconductor substrate and the conductive lines.

3. The semiconductor device of claim 2, wherein an exposed surface of the insulating layer is located at the same plane as the exposed surface of the first semiconductor substrate.

4. The semiconductor device of claim 2, wherein the insulating layer directly contacts the second semiconductor substrate.

5. The semiconductor device of claim 2, wherein a surface of the semiconductor chip exposes the conductive lines, the insulating layer, and the first semiconductor substrate.

6. The semiconductor device of claim 1, wherein the conductive lines have at least one of a bent shape and a curved shape.

7. The semiconductor device of claim 1, wherein the conductive lines are extended toward at least one side surface of the semiconductor chip, and are exposed at the at least one side surface of the semiconductor chip.

8. The semiconductor device of claim 1, wherein the conductive lines directly contact the second semiconductor substrate.

9. The semiconductor device of claim 1, wherein the semiconductor chip further comprises an adhesive layer disposed between the first semiconductor substrate and the second semiconductor substrate.

10. A semiconductor device comprising:
a first semiconductor chip comprising a first surface and a second surface that is opposite to the first surface;
conductive lines embedded in the first surface;
a circuit structure formed in the first semiconductor chip; and
a first external terminal formed on the second surface and electrically connected to the circuit structure,
wherein a substrate surface of the semiconductor substrate and a line surface of the conductive lines are exposed on the first surface, and the exposed substrate and line surfaces are located at the same plane.

11. The semiconductor device of claim 10, wherein the first semiconductor chip further comprises a second external terminal formed on the second surface and electrically connected to the conductive lines.

12. The semiconductor device of claim 10, wherein the first semiconductor chip comprises a circuit region in which the circuit structure is formed, and a connecting region in which the conductive lines are formed.

13. The semiconductor device of claim 10, further comprising:
a second semiconductor chip stacked on the first surface of the first semiconductor chip; and
first bonding wires connected between the second semiconductor chip and the conductive lines.

14. The semiconductor device of claim 13, wherein one of the end portions of the first bonding wires directly contact the exposed surfaces of the conductive lines.

15. The semiconductor device of claim 13, further comprising a printed circuit board, on which the first semiconductor chip is mounted as a flip-chip,
wherein the circuit structure of the first semiconductor chip is electrically connected to the printed circuit board via the first external terminal.

16. The semiconductor device of claim 1, further comprising an external terminal formed on the circuit structure and electrically connected to the circuit structure.

17. A semiconductor device, comprising:
a first semiconductor substrate having a first surface and including at least one conductive line formed in the first semiconductor substrate such that an exposed surface of the at least one conductive line is flush with the first surface of the semiconductor substrate; and
a circuit structure disposed against the first semiconductor substrate and in electrical communication with the at least one conductive line.

18. The semiconductor device of claim 17, wherein the circuit structure is disposed on second surface of the first semiconductor substrate opposite the first surface, and
wherein the at least one conductive line includes a plurality of conductive lines each having an exposed surface being flush with the first surface of the semiconductor substrate.

19. The semiconductor device of claim 18, further comprising:
at least one contact plug having a first end electrically connected to at least one conductive line; and at least one external terminal having a contact pad electrically connected to a second end of the contact plug to electrically connect the at least one external terminal to the at least one conductive line.

20. The semiconductor device of claim 17, further comprising a secondary semiconductor chip disposed directly against each of the first surface of the first substrate and the exposed surface of the conductive lines.
